(19) United States
(12) Patent Application Publication
(10) Pub. No.: US 2023/0287022 A1
(43) Pub. Date: Sep. 14, 2023

(54) Non-Halide Oxygen-Free Organometallic Precursors for ALD/CVD of Metallization

(71) Applicant: Applied Materials, Inc., Santa Clara, CA (US)

(72) Inventors: Byunghoon Yoon, Sunnyvale, CA (US); Yuri Vladimirovich Barsukov, Saint-Petersburg (RU); Avgerinos V. Gelatos, Scotts Valley, CA (US); Joung Joo Lee, San Jose, CA (US)

(73) Assignee: Applied Materials, Inc., Santa Clara, CA (US)

(21) Appl. No.: 17/694,627

(22) Filed: Mar. 14, 2022

(51) Int. Cl. C07F 11/00; C07F 15/00; C09D 1/00; C23C 16/455; C23C 16/18

(52) U.S. Cl. CPC C07F 11/00; C07F 15/0046; C09D 1/00; C23C 16/45525; C23C 16/18

(57) ABSTRACT

Methods for depositing a film using a non-halide oxygen-free organometallic precursors are disclosed. The method includes forming the film on a substrate surface by exposing the surface to the precursor and a reducing agent, the precursor has a general formula (1): M-L₁L₂, wherein M is a metal, L₁ is a first aromatic ligand having a hapticity selected from η³, η⁵, or η⁶, L₂ is a ligand having a hapticity selected from of η³, η⁴, η⁵, η⁶, η⁷, η⁸, η⁹ or η¹⁰. The first aromatic ligand, L₁, may include a structure according to formula (II)

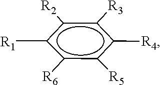

wherein each of R₁, R₂, R₃, R₄, R₅ and R₆ is independently selected from a group consisting of H, methyl, ethyl, n-propyl, isopropyl, n-butyl and iso-butyl. The ligand, L₂, can be independently selected from a group consisting of hexa-1,3,5-triene, 2-methylene-1,3-propanediyl, 1,2-diethenylcyclohex-1-ene, cyclooctatetraene, cyclooctatetraenide anion, styrene, o-quinodimethane, phenyl thiocyanate, phenyl isothiocyanate, (3-methylphenyl)-methylene and derivatives thereof.

### TECHNICAL FIELD

Embodiments of the disclosure pertain to the field of electronic device manufacturing, and in particular, to an integrated circuit (IC) manufacturing. In particular, embodiments of the disclosure pertain to methods for filling surface structures with a metal film.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

The advancing complexity of advanced microelectronic devices is placing stringent demands on currently used deposition techniques. Molybdenum, Ruthenium and Tungsten based films have attractive material and conductive properties. However, processing a Molybdenum, Ruthenium and Tungsten precursor often involves use of halogen and carbonyl-based substituents. These ligands provide sufficient stability at the expense of reduced reactivity, increasing process temperature. Therefore, there is a need in the art for metal precursors that are free of halogen and oxygen that react to form Molybdenum, Ruthenium and Tungsten based films.

### SUMMARY

One or more embodiments of the present disclosure relates to a method of depositing a film. In some embodiments, the method comprising: forming a film on a substrate surface by exposing the substrate surface to an organometallic precursor and a reducing agent, the organometallic precursor comprising a compound having the general formula (I): M-L₁L₂, wherein M is a metal, L₁ is a first aromatic ligand comprising a hapticity selected from of η³, η⁵, or η⁶, L₂ is a ligand comprising a hapticity selected from of η³, η⁴, η⁵, η⁶, η⁷, η⁸, η⁹ or η¹⁰, wherein the first aromatic ligand, L₁, comprises a structure according to Formula II

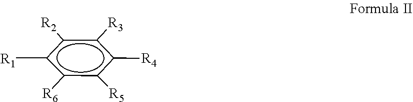

In some embodiments, each of R₁, R₂, R₃, R₄, R₅ and R₆ is independently selected from a group consisting of H, methyl group, ethyl group, n-propyl group, isopropyl group, n-butyl group, and isobutyl group. In some embodiments, the organometallic precursor is free from oxygen and halogen atoms.

In one or more embodiments, the ligand, L₂, is selected from a group consisting of hexa-1,3,5-triene, 2-methylene-1,3-propanediyl, 1,2-diethenylcyclohex-1-ene, cyclooctatetraene, cyclooctatetraenide anion, styrene, o-quinodimethane, phenyl thiocyanate, phenyl isothiocyanate, (3-methylphenyl)-methylene and derivatives thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 shows an exemplary process method according to one or more embodiment of the disclosure; and

FIG. 2 illustrates a schematic view of a processing platform in accordance with one or more embodiments of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Embodiments of the disclosure provide organometallic precursors and processes for depositing metal-containing films. The organometallic precursor comprises a metal coordination complex. The metal coordination complexes of one or more embodiments are substantially free of halogens and oxygen atoms. The process of various embodiments uses vapor deposition techniques, such as an atomic layer deposition (ALD) or chemical vapor deposition (CVD) to provide metal-containing films. The organometallic precursors of one or more embodiments are volatile and thermally stable, and, thus, suitable for vapor deposition.

The metal coordination complexes of one or more embodiments are substantially free of halogen and oxygen atoms. As used herein, the term “substantially free” means that there is less than or equal to 5%, less than 4%, less than 3%, less than 2%, less than %, or less than 0.5% of halogen atoms, on an atomic basis, in the total amount of metal coordination complexes delivered to the processing chamber or to the substrate surface. In some embodiments, the metal coordination complexes are substantially free of oxygen atoms, and there is less than or equal to 5%, including less than or equal to 4%, less than or equal to 3%, less than or equal to 2%, less than or equal to 1%, or less than or equal to 0.5% of oxygen atoms, on an atomic basis, in the metal coordination complexes.

A “substrate” as used herein, refers to any substrate or material surface formed on a substrate upon which film processing is performed during a fabrication process. For example, a substrate surface on which processing can be performed include, but are not limited to, materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the organometallic precursors (or reactive gases) sequentially or substantially sequentially. As used throughout the specification and in the appended claims, “substantially sequentially” means that a majority of the duration of an organometallic precursor exposure does not overlap with the exposure to a co-reagent, although there may be some overlap. In some embodiments, “substantially sequentially” means that flow of co-reagents (or co-reactants) overlap for less than or equal to 5%, 2%, 1% or 0.5% of the total exposure time.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first organometallic precursor or compound A) is pulsed into the reaction zone followed by a first time delay. Next, a second reactive gas (compound B) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas (e.g., non-halide oxygen free organometallic precursors) and second reactive gas (e.g., hydrogen) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Without intending to be bound by theory, it is thought that the presence of halogens and oxygen in the structure of the organometallic precursors can pose challenges, as halogen and oxygen contamination may affect device performance and hence require additional removal procedures. Furthermore, oxygen containing organometallic precursors, such as carbonyl (CO) containing organometallic precursors, binds strongly to metals, requiring higher thermal budget, or the use of additional reagents for its removal. Additionally, carbonyl (CO) can redeposit and poison other metal surfaces.

Reducing the resistance of the via is critical for improved performance of the electronic device. A primary reason for the resistivity increase with decreasing film thickness is electron scattering at external surface and grain boundaries. The resistivity contribution which is proportional to the bulk resistivity and mean free path for electron phonon scattering, the relevant length scale and width or the grain size for surface. Accordingly, the structure dimension for metallization can be controlled by resistivity and mean free path (λρ) of the metal species.

The present disclosure relates to methods for controlling the mean free path (λρ) of the metal species. In some embodiments, the mean free path (λρ) is in a range of from 1×10⁻¹⁷ Ωm² to 1×10⁻¹⁵ Ωm², from 5×10⁻¹⁷ Ωm² to 1×10⁻¹⁵ Ωm², from 1×10⁻¹⁶ Ωm² to 1×10⁻¹⁵ Ωm², from 5×10⁻¹⁶ Ωm² to 1×10⁻¹⁵ Ωm², from 1×10⁻¹⁷ Ωm² to 5×10⁻¹⁶ Ωm², from 5×10⁻¹⁷ Ωm² to 5×10⁻¹⁶ Ωm², from 1×10⁻¹⁶ Ωm² to 5×10⁻¹⁶ Ωm², from 1×10⁻¹⁷ Ωm² to 1×10⁻¹⁶ Ωm², from 5×10⁻¹⁷ Ωm² to 1×10⁻¹⁶ Ωm² or from 1×10⁻¹⁷ Ωm² to 5×10⁻¹⁷ Ωm². In some embodiments, the mean free path (λρ) is less than 1×10⁻¹⁵ Ωm². In some embodiments, the mean free path (λρ) is less or equal to 5×10⁻¹⁶ Ωm² or less or equal to 1×10⁻¹⁶ Ωm². The mean free path of electron from the metal species can be expected less than 15 nm in case the CD size of the structure is less than 10 nm. Accordingly, one or more embodiments of the present disclosure relates to Mo, Ru, W, Co, Rh, Ir and Ni metal species. Some embodiments of the present disclosure relate to Mo, Ru and W. In some embodiments, Mo, Ru or W metal species are good alternate materials to Cu based species for metallization.

A large variety of practical approaches for metallic Ru and Mo deposition processes have been developed through physical & chemical vapor depositions (PVD & CVD), electroplating methods including atomic layer deposition (ALD) techniques using halides or oxygen containing ligands. These commercially available Mo or Ru chemicals are required oxygen combustion reactions and plasma enhanced process for metallization. Accordingly, Mo, W or Ru metal containing molecules can be designed without halogen ligand and oxygen moiety under controlled structure dimension. Because of non-oxygen combustion and plasma free process, in some embodiments, associative reaction mechanism with pi electron ligands was designed with unsaturated and saturated organometallic precursors.

Metal, including but not limited to molybdenum (Mo), ruthenium (Ru) and tungsten (W), can be grown by atomic layer deposition or chemical vapor deposition for many applications. One or more embodiments of the disclosure advantageously provide processes for atomic layer deposition or chemical vapor deposition to form non-halide oxygen free metal-containing films. As used in this specification and the appended claims, the term “metal-containing film” refers to a film that comprises metal atoms and has greater than or equal to 1 atomic % metal, greater than or equal to 2 atomic % metal, greater than or equal to 3 atomic % metal, greater than or equal to 4 atomic % metal, greater than or equal to 5 atomic % metal, greater than or equal to 10 atomic % metal, greater than or equal to 15 atomic % metal, greater than or equal to 20 atomic % metal. In some embodiments, the metal-containing film comprises one or more of elemental metal, metal oxide, metal carbide, metal silicide, or metal nitride. In some embodiments, the major composition of the specified film (i.e., the sum of the atomic percentage of the specified atoms) is greater than or equal to 95%, 98%, 99% or 99.5% of the film, on an atomic basis. In some embodiments, the metal-containing film consists essentially of molybdenum, ruthenium or tungsten. As used in this manner, the term “consists essentially of metal” means that the metal-containing film is greater than or equal to 80%, 85%, 90%, 95%, 98%, 99% or 99.5% metal, on an atomic basis. Measurements of the composition of the metal-containing film refer to the bulk portion of the film, excluding interface regions where diffusion of elements from adjacent films may occur.

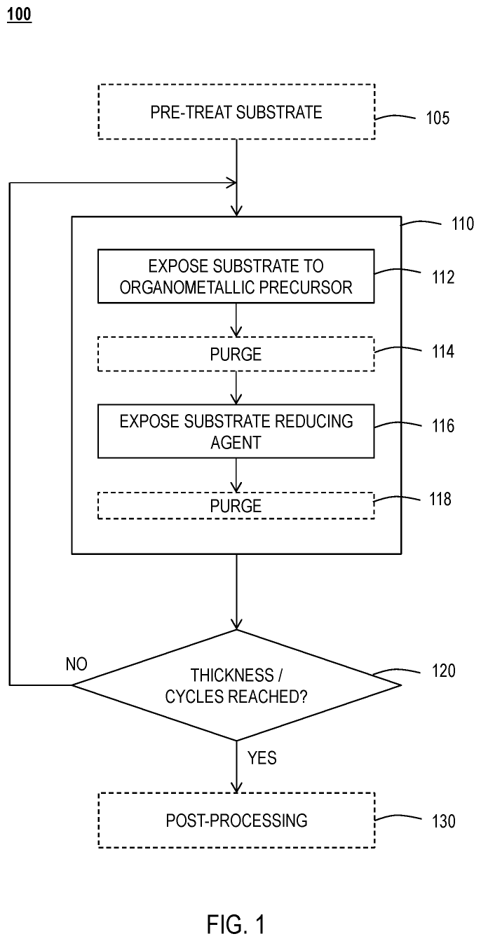

With reference to FIG. 1, one or more embodiments of the disclosure are directed to a method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In some embodiments, the method 100 optionally includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105. In other embodiments, an adhesion layer is not deposited.

At deposition 110, a process is performed to deposit a metal film on the substrate (or substrate surface). The deposition process can include one or more operations to form a film on the substrate. In one or more embodiments, the process is conducted at a temperature in a range of from 100° C. to 500° C. In one or more embodiments, the process is conducted at a pressure in the range of 0.1 Torr to 10 Torr.

At operation 112, the substrate (or substrate surface) is exposed to an organometallic precursor to deposit a film on the substrate (or substrate surface). The organometallic precursor can be any suitable organometallic compound that can react with (i.e., adsorb or chemisorb onto) the substrate surface to leave a metal species on the substrate surface.

In one or more embodiments, the organometallic precursor comprises a compound having the general Formula I:

M-L₁L₂ Formula I

where M is a Metal, L₁ is a first ligand and L₂ is a second ligand.

In one or more embodiments, the metal is selected from the group consisting of molybdenum (Mo), tungsten (W), ruthenium (Ru), Cobalt (Co), Rhodium (Rh), Iridium (Ir) and Nickel (Ni). In some embodiments, the metal is selected from the group consisting of molybdenum (Mo), tungsten (W) and ruthenium (Ru).

In one or more embodiments, the first ligand comprises an aromatic ligand. In some embodiments, the first ligand comprises a hapticity selected from of η³, η⁵, or η⁶. In one or more embodiments, the first ligand comprises a structure according to Formula II:

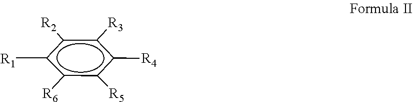

where each of R₁, R₂, R₃, R₄, R₅ and R₆ is independently selected from a group consisting of H and alkyl group. In some embodiments, the alkyl group has a carbon in a range of from 1 to 10. In some embodiments, the alkyl group comprises one or more of a methyl group, ethyl group, n-propyl group, isopropyl group, n-butyl group, t-butyl group, an isobutyl group, five carbon groups (e.g., pentyl groups, cyclopentyl groups), six carbon groups (hexyl groups, cyclohexyl groups) or higher order carbon groups (e.g., heptyl, octyl, nonyl or decyl groups). In some embodiments, the first ligand is asymmetric ligand. Accordingly, in some embodiments, at least one of R₁, R₂, R₃, R₄, R₅ and R₆ is different from the other R groups. In some embodiments, R₁ and R₄ are not same. In some embodiments, R₂ and R₅ are not same. In some embodiments, R₃ and R₆ are not same. In some embodiments, at least one of R₁-R₆ is not hydrogen.

In some embodiments, the first ligand comprises ρ-cymene.

In some embodiments, the second ligand comprises a hapticity selected from of η³, η⁴, η⁵, η⁶, η⁷, η⁸, η⁹ or η¹⁰. In some embodiments, the second ligand comprises a hapticity selected from of η³, η⁵, η⁶, η⁸ or η¹⁰. In one or more embodiments, the second ligand comprises a non-cyclic ligand. In one or more embodiments, the second ligand comprises a cyclic ligand. In one or more embodiments, the cyclic ligand comprises an aromatic ligand and a non-aromatic ligand. In some embodiments, the second ligand is selected from a group consisting of hexa-1,3,5-triene, 2-methylene-1,3-propanediyl, 1,2-diethenylcyclohex-1-ene, cyclooctatetraene, cyclooctatetraenide anion, styrene, o-quinodimethane, phenyl thiocyanate, phenyl isothiocyanate, (3-methylphenyl)-methylene and derivatives thereof.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the metal-containing layer may be at least partially formed thereon. For example, in some embodiments, a layer comprising a metal, a nitride, an oxide, or the like, or combinations thereof may be disposed on the substrate and may have the metal-containing layer formed upon such layer or layers.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the transition metal-containing layer, for example, by polishing, etching, reduction, oxidation, halogenation, hydroxylation, annealing, baking, or the like.

At operation 114, the processing chamber is optionally purged to remove unreacted organometallic precursor, reaction products and by-products. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the organometallic precursor by any suitable technique including, but not limited to, moving the substrate through a gas curtain to a portion or sector of the processing chamber that contains none or substantially none of the organometallic precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

In one or more embodiments, at operation 116, the organometallic precursor-containing metal film is exposed to a reducing agent. In some embodiments, the organometallic precursor-containing metal film is exposed to the reducing agent at a concentration in a range of from 1 sccm to 500 sccm, from 10 sccm to 500 sccm, from 100 sccm to 500 sccm, from 200 sccm to 500 sccm, from 1 sccm to 200 sccm, from 10 sccm to 200 sccm, from 100 sccm to 200 sccm, from 1 sccm to 100 sccm, from 10 sccm to 100 sccm or from 1 sccm to 10 sccm. In some embodiments, the organometallic precursor-containing metal film is exposed to the reducing agent at a pressure in a range of from 100 mTorr to 100 Torr, from 1 Torr to 100 Torr, from 10 Torr to 100 Torr, from 100 mTorr to 10 Torr, from 1 Torr to 10 Torr or from 100 mTorr to 1 Torr. In one or more embodiments, exposure to the reducing agent forms the metal-containing film. In some embodiments, the metal-containing film is a high purity metal film. In one or more embodiments, the reducing agent can comprise any reducing agent known to one of skill in the art.

In some embodiments, the reducing agent comprises hydrogen (H₂), hydrazine (N₂H₄) and hydrazine derivatives and atomic iodine as surface adatom. In some embodiments, the hydrogen (H₂) comprises thermal hydrogen (H₂) and/or hydrogen (H₂) plasma.

The period of time of each operation in deposition 110 can be varied in order to form a deposited film (e.g., the metal-containing film) of a predetermined thickness.

At decision 120, the thickness of the deposited film, or number of cycles of organometallic precursor, iodine-containing reactant, and reductant is considered. If the deposited film has reached a predetermined thickness or a predetermined number of process cycles have been performed, the method 100 moves to an optional post-processing operation 130. If the thickness of the deposited film or the number of process cycles has not reached the predetermined threshold, the method 100 returns to operation 110 to expose the substrate surface to the organometallic precursor again in operation 112 and continues processing. In some embodiments, the period of time for each cycle is in a range of from 1 second to 100 seconds. In some embodiments, the cycle or ALD cycle comprises metal precursor pulse, Ar purge, reducing agent pulse and Ar purge.

In one or more embodiments, the deposited film (e.g., the metal-containing film) has a thickness in a range of from 0.1 Å to 10 Å, from 1 Å to 10 Å, from 5 Å to 10 Å, from 0.1 Å to 5 Å, from 1 Å to 5 Å or from 0.1 Å to 1 Å.

In one or more embodiments, the deposited film (e.g., the metal film) has a resistivity ρ (μΩcm)×mean free path λ (nm) less than or equal to 5×10⁻¹⁶ Ωm². In one or more embodiments, the deposited film (e.g., the metal film) has a resistivity less than or equal to 1×10⁻¹⁶ Ωm², or less than or equal to 5×10⁻¹⁶ Ωm².

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited film. In some embodiments, the optional post-processing operation 130 comprises annealing the as-deposited film. In some embodiments, annealing is done at temperatures in the range of from 300° C. to 900° C., from 300° C. to 600° C. or from 300° C. to 600° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of 15 seconds to 90 minutes, or in the range of 1 minute to 60 minutes. In some embodiments, annealing the as-deposited film increases the density, decreases the resistivity and/or increases the purity of the film. In one or more embodiments, annealing can also with performed with a gas under plasma. In one or more embodiments, the annealing temperature may be lower with plasma.

The method 100 can be performed at any suitable temperature depending on, for example, the organometallic precursor, reducing agent, or thermal budget of the device. In one or more embodiments, the use of high temperature processing may be undesirable for temperature-sensitive substrates, such as logic devices. In some embodiments, exposure to the organometallic precursor (operation 112) and the reducing agent (operation 116) occur at the same temperature. In some embodiments, the substrate is maintained at a temperature in a range of 100° C. to 500° C.

In some embodiments, exposure to the organometallic precursor (operation 112) and the reducing agent (operation 116) occurs at a different temperature. In one or more embodiments, the substrate surface is exposed to the organometallic precursor (operation 112) at a first temperature and to the reducing agent (operation 120) at a second temperature different from the first temperature. In one or more embodiments, the first temperature is in a range from 100° C. to 500° C., for the exposure to the organometallic precursor (operation 112) and the second temperature is in a range from 0° C. to 500° C., from 100° C. to 500° C., from 300° C. to 500° C., from 0° C. to 300° C., from 100° C. to 300° C. or from 0° C. to 100° C. for the exposure to the reducing agent (operation 116).

In the embodiment illustrated in FIG. 1, at deposition operation 110 the substrate (or substrate surface) is exposed to the organometallic precursor and the reducing agent sequentially.

In another, un-illustrated, embodiment, the film is deposited in a CVD reaction. Accordingly, in some embodiments, the substrate (or substrate surface) is exposed to the organometallic precursor and the reducing agent simultaneously in a CVD reaction. In the CVD reaction, the deposited film (e.g., the metal film) can be deposited in one exposure to the mixed reactive gas or can be multiple exposures to the mixed reactive gas with purges between.

In another, un-illustrated, embodiment, the film is deposited in a pulsed-CVD reaction. Accordingly, in some embodiments, the substrate is exposed to the organometallic precursor constantly and the reducing agent intermittently. Stated differently, in some embodiments, the methods are pulsed-CVD type methods where one reactant is flowed constantly, and the other is pulsed at a regular interval into the chamber. In some embodiments, the substrate is exposed to the organometallic precursor for a period before being exposed to the reducing agent and the organometallic precursor simultaneously.

In spatial ALD embodiments, exposure to each of the process gases occurs simultaneously to different parts of the substrate so that one part of the substrate is exposed to the first reactive gas while a different part of the substrate is exposed to the second reactive gas (if only two reactive gases are used). The substrate is moved relative to the gas delivery system so that each point on the substrate is sequentially exposed to both the first and second reactive gases. In any embodiment of a time-domain ALD or spatial ALD process, the sequence may be repeated until a predetermined layer thickness is formed on the substrate surface.

Some embodiments of the disclosure are directed to processes that use a reaction chamber with multiple gas ports that can be used for introduction of different chemicals or plasma gases. Spatially, these gas ports (also referred to as channels) are separated by inert purging gases and/or vacuum pumping holes to create a gas curtain that minimizes or eliminates mixing of gases from different gas ports to avoid unwanted gas phase reactions. Wafers moving through these different spatially separated ports get sequential and multiple surface exposures to different chemical or plasma environment so that layer by layer film growth in spatial ALD mode or surface etching process occur. In some embodiments, the processing chamber has modular architectures on gas distribution components and each modular component has independent parameter control (e.g., RF or gas flow) to provide flexibility to control, for example, gas flow and/or RF exposure.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described in this disclosure.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In one or more embodiments, oxygen-free and non-halide molecular systems showed good step coverage and conformal gap fill performance when the unsaturated and saturated organometallic precursors, such as Mo, W and Ru based organometallic precursors, are incorporated with hydrogen as co-reactant or surface reaction catalyst.

One or more embodiments of the disclosure are directed to methods of depositing metal films in high aspect ratio features. A high aspect ratio feature is a trench, via or pillar having a height:width ratio greater than or equal to 10, 20, or 50, or more. In some embodiments, the metal film is deposited conformally on the high aspect ratio feature.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved around a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

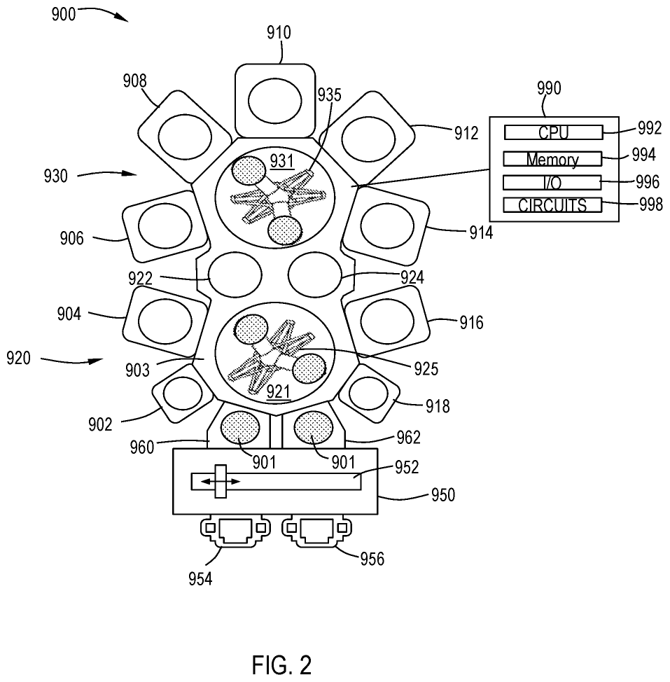

Additional embodiments of the disclosure are directed to processing tools 900 for the formation of the devices and practice of the methods described, as shown in FIG. 2. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a physical vapor deposition chamber, a UV curing chamber, an ICP chamber, an etching chamber, and the like. The particular arrangement of process chambers and components can be varied depending on the cluster tool and should not be taken as limiting the scope of the disclosure.

In the embodiment shown in FIG. 2, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU) 992, memory 994, inputs/outputs (I/O) 996, and support circuits 998. The controller 990 may control the processing tool 900 directly, or via computers (or controllers) associated with particular process chamber and/or support system components.

In one or more embodiments, the controller 990 may be one of any form of general-purpose computer processor that can be used in an industrial setting for controlling various chambers and sub-processors. The memory 994 or computer readable medium of the controller 990 may be one or more of readily available memory such as non-transitory memory (e.g. random access memory (RAM)), read only memory (ROM), floppy disk, hard disk, optical storage media (e.g., compact disc or digital video disc), flash drive, or any other form of digital storage, local or remote. The memory 994 can retain an instruction set that is operable by the processor (CPU 992) to control parameters and components of the processing tool 900.

The support circuits 998 are coupled to the CPU 992 for supporting the processor in a conventional manner. These circuits include cache, power supplies, clock circuits, input/output circuitry and subsystems, and the like. One or more processes may be stored in the memory 994 as software routine that, when executed or invoked by the processor, causes the processor to control the operation of the processing tool 900 or individual processing units in the manner described herein. The software routine may also be stored and/or executed by a second CPU (not shown) that is remotely located from the hardware being controlled by the CPU 992.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 990 has one or more configurations to execute individual processes or sub-processes to perform the method. The controller 990 can be connected to and configured to operate intermediate components to perform the functions of the methods. For example, the controller 990 can be connected to and configured to control a physical vapor deposition chamber.

Processes may generally be stored in the memory 994 of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the system controller 990 has a configuration to control a chemical vapor deposition chamber to deposit a film on a wafer at a temperature in the range of about 20° C. to about 400° C. and control a remote plasma source to form a polysilazane film on the wafer.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a physical vapor deposition chamber and a remote plasma source; a UV curing chamber; an ICP chamber; and a controller connected to the central transfer station and the plurality of process stations, the controller configured to activate the robot to move the wafer between process stations, and to control a process occurring in each of the process stations.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

In the foregoing specification, embodiments of the disclosure have been described with reference to specific exemplary embodiments thereof. It will be evident that various modifications may be made thereto without departing from the broader spirit and scope of the embodiments of the disclosure as set forth in the following claims. The specification and drawings are, accordingly, to be regarded in an illustrative sense rather than a restrictive sense.

What is claimed is:

1. A method of depositing a film, the method comprising:
forming a film on a substrate surface by exposing the substrate surface to an organometallic precursor and a reducing agent, the organometallic precursor comprising a compound having the general formula (I): M-L₁L₂,
wherein M is a metal, L₁ is a first aromatic ligand comprising a hapticity selected from of η³, η⁵, or η⁶, L₂ is a ligand comprising a hapticity selected from of η³, η⁴, η⁵, η⁶, η⁷, η⁸, η⁹ or η¹⁰,
wherein the first aromatic ligand, L₁, comprises a structure according to Formula II 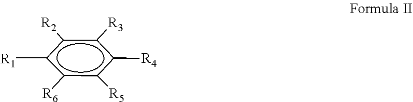
wherein, each of R₁, R₂, R₃, R₄, R₅ and R₆ is independently selected from a group consisting of H, methyl group, ethyl group, n-propyl group, isopropyl group, n-butyl group and iso-butyl group, and
wherein the organometallic precursor is free from oxygen and halogen atoms.

2. The method of claim 1, wherein the metal M is selected from one or more of molybdenum (Mo), ruthenium (Ru), tungsten (W), Cobalt (Co), Rhodium (Rh), Iridium (Ir) or Nickel (Ni).

3. The method of claim 1, wherein the first aromatic ligand, L₁, comprises ρ-cymene.

4. The method of claim 1, wherein the ligand, L₂, comprises a non-cyclic ligand.

5. The method of claim 4, wherein the non-cyclic ligand is selected from a group consisting of hexa-1,3,5-triene, 2-methylene-1,3-propanediyl and derivatives thereof.

6. The method of claim 1, wherein the ligand, L₂, comprises a cyclic ligand.

7. The method of claim 6, wherein the cyclic ligand is a non-aromatic ligand.

8. The method of claim 7, wherein the non-aromatic ligand is selected from a group consisting of 1,2-diethenylcyclohex-1-ene, cyclooctatetraene and derivatives thereof.

9. The method of claim 6, wherein the cyclic ligand is a second aromatic ligand.

10. The method of claim 9, wherein the second aromatic ligand is selected from a group consisting of cyclooctatetraenide anion, styrene, o-quinodimethane, phenyl thiocyanate, phenyl isothiocyanate, (3-methylphenyl)-methylene and derivatives thereof.

11. The method of claim 1, wherein the reducing agent comprises one or more of hydrogen (H₂) hydrazine (N₂H₄), hydrazine derivatives or iodine adatom.

12. The method of claim 1, wherein the substrate surface is exposed to the organometallic precursor and the reducing agent sequentially or simultaneously.

13. A method of depositing a film, the method comprising:
forming a film on a substrate surface by exposing the substrate surface to an organometallic precursor and a reducing agent, the organometallic precursor comprising a compound having the general formula (I): M-L₁L₂,
wherein M is a metal, L₁ is a first aromatic ligand comprising a hapticity selected from η³, η⁵, or η⁶, L₂ is a ligand comprising a hapticity selected from of η³, η⁴, η⁵, η⁶, η⁷, η⁸, η⁹ or η¹⁰,
wherein the ligand, L₂, is selected from a group consisting of hexa-1,3,5-triene, 2-methylene-1,3-propanediyl, 1,2-diethenylcyclohex-1-ene, cyclooctatetraene, cyclooctatetraenide anion, styrene, o-quinodimethane, phenyl thiocyanate, phenyl isothiocyanate, (3-methylphenyl)-methylene and derivatives thereof, and
wherein the organometallic precursor is free from oxygen and halogen atoms.

14. The method of claim 13, wherein the metal M is selected from one or more of molybdenum (Mo), ruthenium (Ru), tungsten (W), Cobalt (Co), Rhodium (Rh), Iridium (Ir) or Nickel (Ni).

15. The method of claim 13, wherein the first aromatic ligand, L₁, comprises a structure according to Formula II 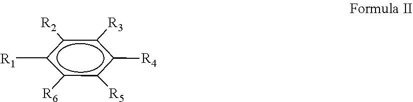
wherein, each of R₁, R₂, R₃, R₄, R₅ and R₆ is independently selected from a group consisting of H methyl group, ethyl group, n-propyl group, isopropyl group, n-butyl group, and iso-butyl group.

16. The method of claim 13, wherein the first aromatic ligand, L₁, comprises ρ-cymene.

17. The method of claim 13, wherein the reducing agent comprises hydrogen (H₂), hydrazine (N₂H₄) derivatives and iodine adatom.

18. The method of claim 13, wherein the substrate surface is exposed to the organometallic precursor and the reducing agent sequentially or simultaneously.
